(19) United States
(12) Patent Application Publication
(10) Pub. No.: US 2025/0065469 A1
(43) Pub. Date: Feb. 27, 2025

(54) SUBSTRATE POLISHING DEVICE, SUBSTRATE PROCESSING SYSTEM AND POLISHING METHOD USING THE SAME

(71) Applicant: Samsung Electronics Co., Ltd., Suwon-si (KR)

(72) Inventor: DONGHOON KWON, Suwon-si (KR)

(21) Appl. No.: 18/434,492

(22) Filed: Feb. 6, 2024

(30) Foreign Application Priority Data
Aug. 21, 2023 (KR) 10-2023-0109151

(51) Int. Cl. B24B 37/27; B24B 37/34; B24B 51/00

(52) U.S. Cl. CPC B24B 37/27; B24B 37/34; B24B 51/00

(57) ABSTRACT

A substrate polishing device according to an embodiment includes a first polishing module disposed in a first region and including a plurality of first polishing units having first polishing pads, a second polishing module disposed in a second region and including at least one second polishing unit having a second polishing pad, and a transfer module configured to transfer a substrate between the first polishing module and the second polishing module. The second region is disposed adjacent to or within the first region, and a diameter of the second polishing pad is smaller than a diameter of the first polishing pad.

### CROSS-REFERENCE TO RELATED APPLICATION

This application claims priority under 35 U.S.C. § 119 to and the benefit of Korcan Patent Application No. 10-2023-0109151 filed in the Korean Intellectual Property Office on Aug. 21, 2023, the entire content of which is incorporated herein by reference.

### BACKGROUND OF THE INVENTION

### (a) Field of the Invention

The present disclosure relates to a substrate polishing device, a substrate processing system, and a polishing method using the same.

### (b) Description of the Related Art

Chemical mechanical polishing (CMP) process, which planarizes semiconductor substrates, is a process of polishing various thin films on the substrate to planarize or remove the surface of the substrate by making chemical changes to the surface of the material to be polished to facilitate mechanical polishing.

The CMP process may remove steps on the surface of a substrate or remove a film by changing the film surface to a soft state for polishing by a chemical reaction, and then remove the softened surface by mechanical polishing using a pad rotating at high speed.

The CMP process is a highly precise process in which not only mechanical factors such as the rotation speed of the polishing pad and the substrate, the pressure applied to the substrate, and the pattern direction of the polishing pad act as important process variables, but also chemical influences such as the interaction between slurry polishing particles and the substrate surface and the role of the slurry organic additives that also act as important process variables.

Depending on each process condition, scratches or particles may occur due to inappropriate vertical pressure, worn pad, insufficient conditioning, slurry residue and drying, and thin film adherence. Therefore, it is necessary to adjust various process parameters such as polishing speed, flatness, uniformity, and selectivity according to the required process conditions to achieve desired polishing. There is a need for technological development to improve process efficiency in the substrate processing process under various process conditions.

### SUMMARY OF THE INVENTION

The present disclosure is proposed to solve the above issues, and attempts to provide a substrate polishing device, a substrate processing system, and a polishing method using the same, wherein a second polishing module is disposed adjacent to a first polishing module to enable a second polishing process with different process conditions to proceed before and after the first polishing process, thereby increasing the efficiency of the polishing process, in a chemical mechanical polishing (CMP) device.

A substrate polishing device according to an embodiment includes a first polishing module disposed in a first region and including a plurality of first polishing units having first polishing pads, a second polishing module disposed in a second region and including at least one second polishing unit having a second polishing pad, and a transfer module configured to transfer a substrate between the first polishing module and the second polishing module. The second region is disposed adjacent to or within the first region, and a diameter of the second polishing pad is smaller than a diameter of the first polishing pad.

A substrate processing system according to an embodiment includes a substrate polishing device including a first polishing module including a plurality of first polishing units having first polishing pads, and a second polishing module including at least one second polishing unit having a second polishing pad, wherein a diameter of the second polishing pad is smaller than a diameter of the first polishing pad, a cleaning module disposed adjacent to the substrate polishing device to perform a cleaning process, and a transfer module configured to transfer the substrate from the substrate polishing device and the cleaning module. The second polishing module is disposed between the first polishing module and the cleaning module or is disposed within the first polishing module.

A substrate polishing method according to an embodiment includes performing a first polishing process in a first polishing module including a first polishing unit, performing a second polishing process during at least one of before and after the first polishing process in a second polishing module including a second polishing unit, and transferring the substrate from the first polishing module to the second polishing module or from the second polishing module to the first polishing module. A first region where the first polishing module is disposed is disposed adjacent to a second region where the second polishing module is disposed, or the second region is disposed within the first region. A diameter of a second polishing pad of the second polishing unit is smaller than a diameter of a first polishing pad of the first polishing unit.

According to embodiments, the first polishing module and the second polishing module, which can set different process conditions, are installed close to each other to minimize the volume of the substrate polishing device while allowing polishing to be performed under various conditions, thereby improving the performance of substrate processing.

### BRIEF DESCRIPTION OF THE DRAWINGS

FIG. 1A is a diagram illustrating an example of a substrate polishing device.

FIG. 1B is a diagram illustrating an example of a substrate polishing device.

FIG. 2A is a diagram illustrating a substrate polishing device according to an embodiment.

FIG. 2B is a diagram illustrating the configuration of a substrate polishing apparatus according to an embodiment.

FIG. 2C is a diagram illustrating a second polishing module according to an embodiment.

FIG. 3A is a diagram illustrating a substrate processing system according to another embodiment.

FIG. 3B is a diagram illustrating a substrate processing system according to another embodiment.

FIG. 3C is a diagram illustrating a substrate processing system according to another embodiment.

FIG. 3D is a diagram illustrating a substrate processing system according to another embodiment.

FIG. 3E is a diagram illustrating the operation process of the substrate processing system according to FIG. 3D.

FIG. 3F is a diagram illustrating the operation process of the substrate processing system according to FIG. 3D.

FIG. 4A is a diagram illustrating the operation process of the substrate processing system according to FIG. 3A.

FIG. 4B is a diagram illustrating the operation process of the substrate processing system according to FIG. 3A.

FIG. 5A is a diagram illustrating a substrate loading process into a second polishing module according to an embodiment.

FIG. 5B is a diagram illustrating a substrate loading process into a second polishing module according to an embodiment.

FIG. 5C is a diagram illustrating a substrate loading process into a second polishing module according to an embodiment.

FIG. 5D is a diagram illustrating a substrate loading process into a second polishing module according to an embodiment.

FIG. 5E is a diagram illustrating a substrate loading process into a second polishing module according to an embodiment.

### DETAILED DESCRIPTION OF THE EMBODIMENTS

Hereinafter, the present disclosure will be described in detail with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, size and thickness of each constituent clement in the drawings are arbitrarily illustrated for better understanding and case of description, the following embodiments are not limited thereto. In the drawings, the thickness of layers, films, panels, regions, etc., are exaggerated for clarity. In the drawings, the thickness of some layers and regions may be exaggerated for case of description.

Throughout this specification and the claims that follow, when it is described that an element is “coupled” to another element, it includes not only the case of being “directly coupled” but also “indirectly coupled” with another element therebetween. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

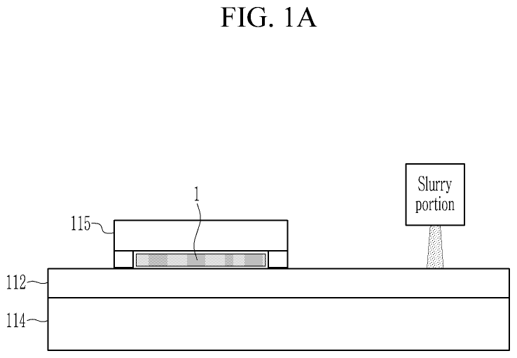

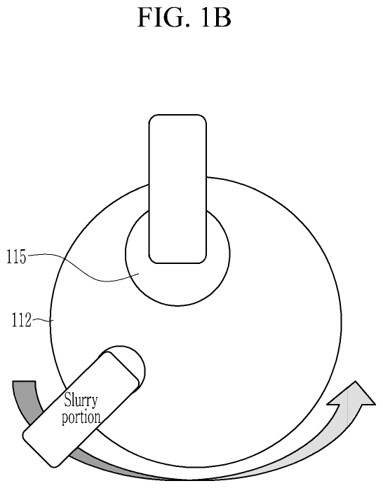

FIGS. 1A and 1B are diagrams illustrating an example of a substrate polishing device.

A substrate polishing device, through chemical mechanical polishing (CMP), may polish the surface of a substrate 1 by supplying slurry between the surface of the substrate 1 and a polishing surface of a first polishing pad 112 disposed on a first supporting member 114, and rotating the substrate 1 and the first polishing pad 112 in contact with each other.

For example, a slurry containing a fine abrasive is sprayed onto the first polishing pad 112 through the slurry portion, and the surface of the substrate I to be polished is placed on the first polishing pad 112 and rotated while applying pressure through a first head portion 115 to polish the surface of the substrate 1.

In this case, the mechanical polishing component acts to aid in planarizing as areas of different heights on the surface of the substrate 1 are subjected to different pressures upon contact with the first polishing pad 112, with the relatively higher areas grinding first due to the higher pressure.

In the polishing process, it is not easy to handle the substrate 1 requiring different polishing conditions with a single polishing device, because the polishing result depends not only on mechanical factors such as the rotation speed of the first polishing pad 112 and the substrate 1, the pressure applied to the substrate 1, the pattern orientation of the first polishing pad 112, but also on the interaction between the slurry polishing particles and the surface of the substrate 1, the slurry organic additives, and the like.

For example, after depositing the substrate 1, the roughness of the substrate 1 causes a polishing time retardation phenomenon at the beginning of the CMP process. If the roughness of the substrate 1 is removed before the main polishing process proceeds, the productivity of the main polishing process may be increased. However, it is not easy to perform the process of removing the roughness of the substrate 1 in advance in the polishing module where the main polishing process will be performed.

Accordingly, in the subsequently described substrate polishing device 10 and the substrate processing system 20 according to the present disclosure, the purpose is to add an auxiliary polishing device capable of performing an additional polishing process before and after the main polishing process. The polishing device is disposed close to or within the first region where the main polishing process is performed, so that the substrates 1 may easily undergo the auxiliary polishing process before and after the main polishing process.

In the auxiliary polishing process, unlike the main polishing process, the polishing work is performed according to the required area and conditions rather than polishing the entire substrate 1, so the polishing equipment in the auxiliary polishing process may have a smaller size than the main polishing equipment, and the area occupied by the polishing module is also small, so that the auxiliary polishing process may be performed without increasing the space of the entire polishing device.

Hereinafter, the substrate polishing device 10, the substrate processing system 20, and the polishing method using the same according to an embodiment of the present disclosure will be described in more detail with reference to the drawings.

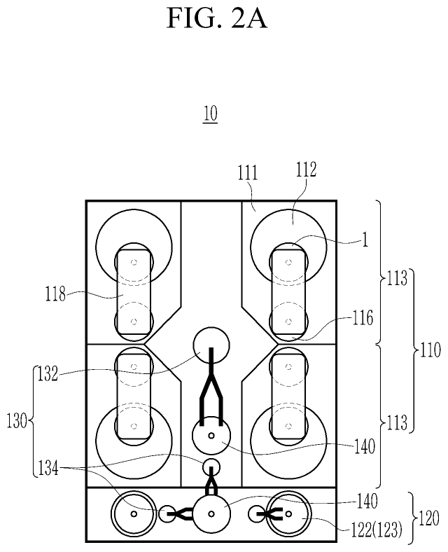

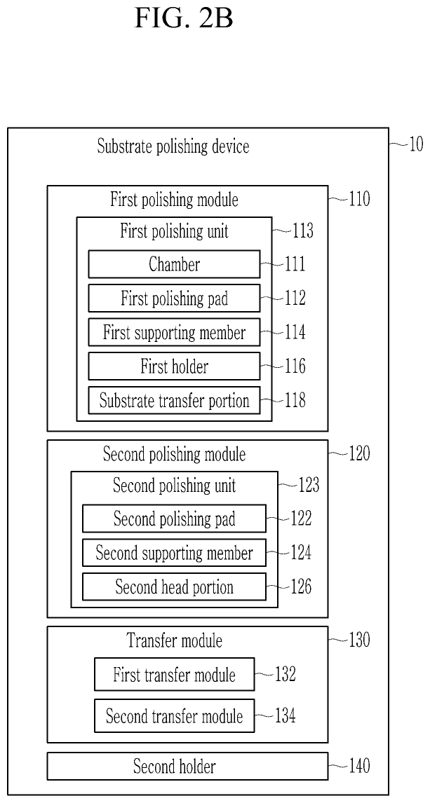

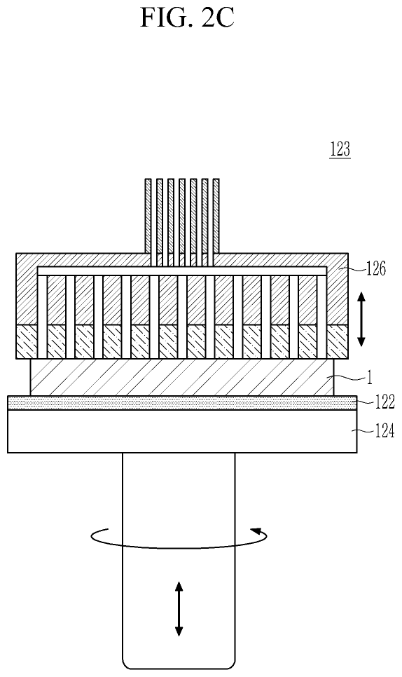

FIG. 2A is a diagram illustrating a substrate polishing device according to an embodiment. FIG. 2B is a diagram illustrating the configuration of a substrate polishing device according to an embodiment. FIG. 2C is a diagram illustrating a second polishing module according to an embodiment.

As shown in FIGS. 2A to 2C, the substrate polishing device 10 according to the present disclosure may include a first polishing module 110 including a plurality of first polishing units 113 having first polishing pads 112, a second polishing module 120 including at least one second polishing unit 123 having a second polishing pad 122, and a transfer module 130 transferring the substrate 1 between the first polishing module 110 and the second polishing module 120. A diameter of the second polishing pad 122 may be smaller than a diameter of the first polishing pad 112.

The region where the first polishing module 110 is disposed is referred to as the first region, and the region where the second polishing module 120 is disposed is referred to as the second region, where the second region may be adjacent to or within the first region.

First, in FIG. 2A, the second region is shown as being disposed on one side of the first region. This is because the second polishing module 120 is disposed close to or within the first region where the first polishing module 110 is disposed, so that the substrates 1 can easily perform the second polishing process before and after the first polishing process.

The number of the first polishing units 113 may be greater than the number of the second polishing units 123. The first polishing module 110 disposed in the first region includes a plurality of first polishing units 113, and the second polishing module 120 disposed in the second region includes at least one second polishing unit 123. Four first polishing units 113 and two second polishing units 123 are shown in FIG. 2A, but the number is not limited to what is shown.

Two or more first polishing units 113 and one or more second polishing units 123 may be disposed, such that the number of the first polishing units 113 may be greater than the number of the second polishing units 123.

The diameter of at least one of the upper surfaces of the second polishing pad 122 and the second supporting member 124 disposed below the second polishing pad 122 may be 1.2 times or less the diameter of the substrate 1.

Referring to FIG. 2C, the diameter of the upper surface of the second supporting member 124 disposed below the second polishing pad 122 and the diameter of the second polishing pad 122 are smaller than 1.2 times the diameter of the substrate 1. In some cases, the second polishing pad 122 may have a diameter smaller than the diameter of the substrate 1. The second polishing pad 122 may also include the second supporting member 124.

The second supporting member 124 and the second polishing pad 122 of the second polishing module 120 have a smaller size than the first supporting member 114 and the first polishing pad 112 of the second polishing module 120. This is because, unlike in the first polishing module 110 in which a polishing operation is performed on the entire substrate 1, in the second polishing module 120, the operation is performed before and after the first polishing process, in accordance with a required process, a required area of the substrate 1, and required conditions, therefore, the second polishing module 120 may have a smaller size than the first polishing module 110.

Due to the small diameter of the second polishing pad 122 and the second supporting member 124 included in the second polishing module 120, the equipment size of the second polishing module 120 is smaller than that of the first polishing module 110. In addition, the number of the second polishing units 123 disposed in the second polishing module 120 is always 1 less than the number of the first polishing units 113 disposed in the first polishing module 110. Therefore, the area of the second region where the second polishing module 120 is disposed may be smaller than the area of the first region where the first polishing module 110 is disposed.

Preferably, the area of the second region may be 70% or less of the area of the first region. The above area means the area on a plane.

In addition, as the second region is disposed adjacent to or within the first region, so that the area included in the second region in the entire substrate polishing device 10 does not occupy a large proportion, and there is no separate movement line for the substrate 1 between each first polishing module 110 and the second polishing module 120, an advantage of minimizing the increase in the entire facility area is provided.

The first polishing module 110, i.e., each of the four first polishing units 113 disposed in the first region of FIG. 2A, may include a chamber 111 in which the first polishing process takes place, a first supporting member 114 rotating about an axis in a direction vertical to the substrate 1 within the chamber 111, and the first polishing pad 112 disposed on the upper surface of the first supporting member 114. The substrate 1 may be loaded into the first polishing module 110 and the first polishing module 110 may polish the substrate 1 during the polishing process (see FIG. 1A).

The first polishing module 110 may also include a first head portion 115 that is rotatable and liftable about an axis in a direction vertical to the first supporting member 114 to press the substrate 1 toward the first polishing pad 112 from the top of the first polishing pad 112.

The first polishing module 110 may also include a first holder 116 disposed adjacent to the first polishing pad 112. The first holder 116 may hold the substrate 1 within the chamber 111 before the substrate 1 is loaded onto the first polishing pad 112 and may hold the substrate 1 after the substrate 1 is unloaded from the first polishing pad 112.

The first holder 116 is used to hold the substrate 1 before the substrate 1 is polished in the first chamber 111 and is used to hold the substrate I after the substrate 1 is polished in the first chamber 111. The first holder 116 may be any size or shape that allows the substrate 1 to be held.

The first polishing module 110 may further include a substrate transfer portion 118. The substrate transfer portion 118 may transfer the substrate 1 between the first holder 116 and the first polishing pad 112. For example, the substrate transfer portion 118 disposed in each chamber 111 may unload the polished substrate 1 from the first polishing pad 112 and transfer the substrate 1 to the first holder 116 after the first polishing process. In another example, the substrate transfer portion 118 may enter the respective chamber 111 from the outside and may transfer the substrate 1 placed on the first holder 116 to the first polishing pad 112 and load the substrate I onto the first polishing pad 112 to proceed with the first polishing process.

The substrate transfer portion 118, which serves to load and unload the substrate 1 within the chamber 111 of the first polishing unit 113, may be a turret type structure in which the arm rotates, but is not limited thereto.

The substrate polishing device 10 according to the present disclosure may include the transfer module 130 transferring the substrate 1 between the first polishing module 110 and the second polishing module 120.

The transfer module 130 may transfer the substrate 1 to and from the first polishing units 113 included within the first polishing module 110, may transfer the substrate 1 between the within the first polishing module 110 and the second polishing module 120, and may transfer the substrate 1 within the second polishing module 120.

The transfer module 130 may include a first transfer module 132 for transferring the substrate 1 within the first region (e.g., to and from the first polishing units 113 included within the first polishing module), and a second transfer module 134 for transferring the substrate 1 between the first region and the second region and within the second region.

The first transfer module 132 may transfer the substrate 1 to the first holder 116 in the chamber 111, or may transfer the substrate 1 in the first holder 116 out of the chamber 111, or may transfer the substrate 1 while moving between the chambers 111, that is, between the first polishing units 113, among the first region where the first polishing module 110 is disposed.

In FIG. 2A, four first polishing units 113 are disposed in the first polishing module 110, and the first transfer module 132 moves through a vertical passage between each chamber 111, and the substrate 1 may be transferred.

Depending on embodiments, a second holder 140 may be disposed in an area transitioning from the first region to the second region, as shown in FIG. 2A. For example, as illustrated in FIG. 2A a second holder 140 may be included in the first polishing module 110 (i.e., in the first region). When the first transfer module 132 places the substrate 1 on the second holder 140 in the first region adjacent to the second region, the second transfer module 134 may then transfer the substrate 1 from the second holder 140 of the first region to the second region.

The second transfer module 134 transfers the substrate 1 between the first and second regions and transfers the substrate 1 within the second region. The second transfer module 134 may also transfer the substrate 1 from the second holder 140 disposed in the first region to the second region, as described above.

As shown in FIG. 2A, a second holder 140 may also be included in the second polishing module 120 (i.e., in the second region). The transfer module 134 may place the substrate 1 that has entered the second region on the second holder 140 included in the second polishing module 120.

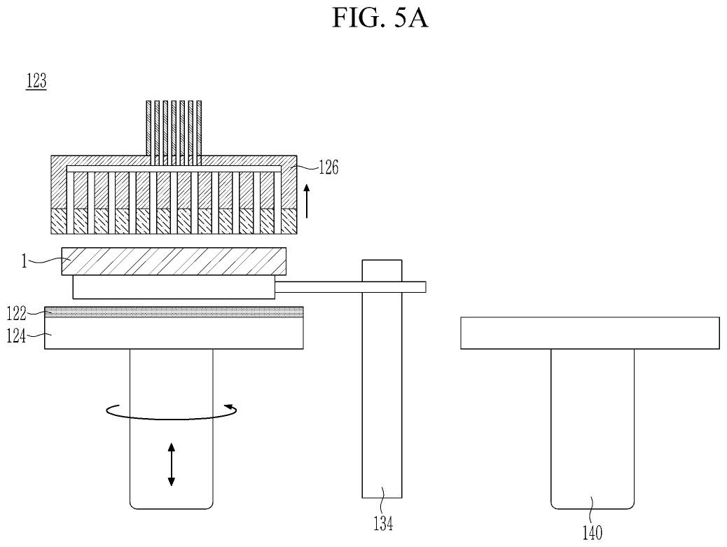

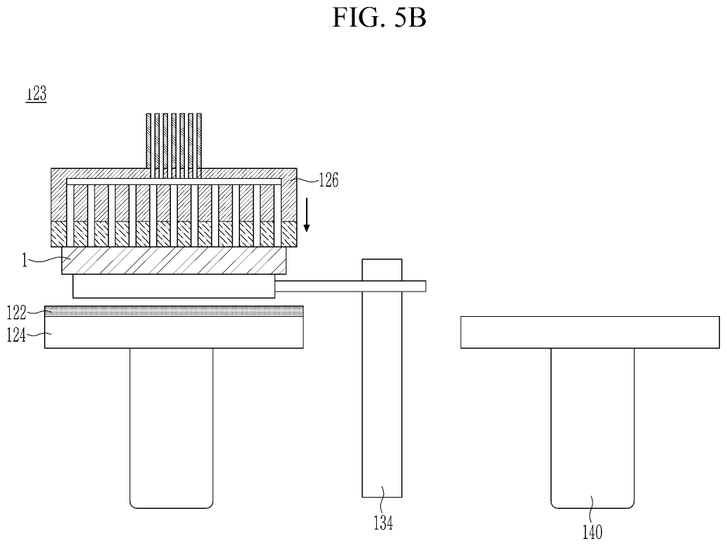

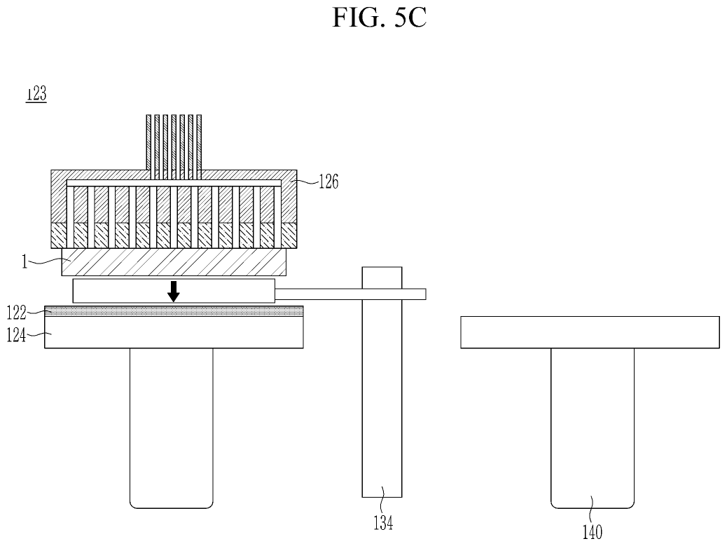

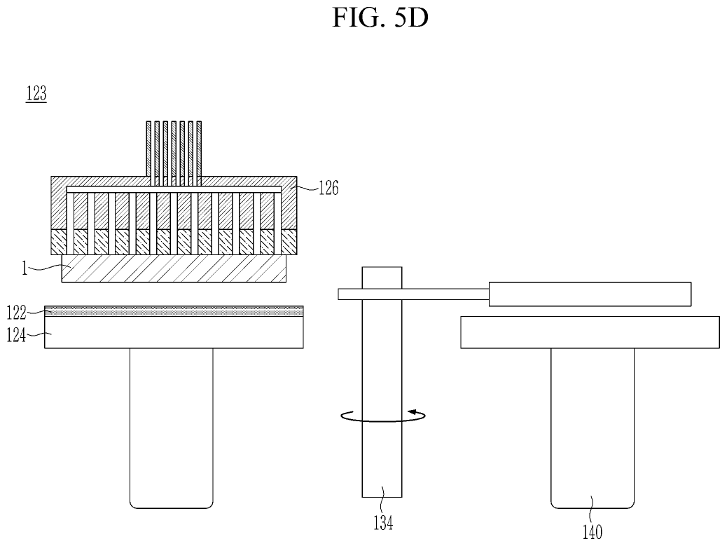

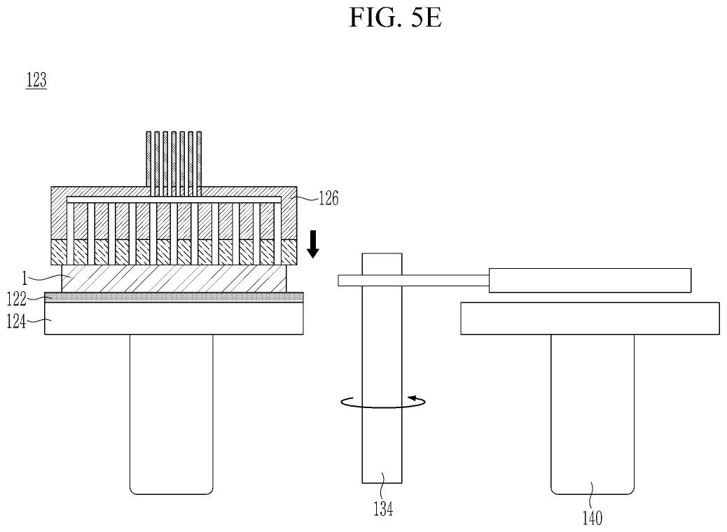

The substrate 1 placed on the second holder 140 in the second region may be transferred to be loaded on the second polishing pad 122 by the second transfer module 134. The loading process into the second polishing module 120 will be described in detail in FIGS. 5A to 5E below.

The second transfer module 134 may be smaller in size than the first transfer module 132, the first transfer module 132 and the second transfer module 134 may be a robot structure equipped with an articulated arm, and the robot may be waterproof.

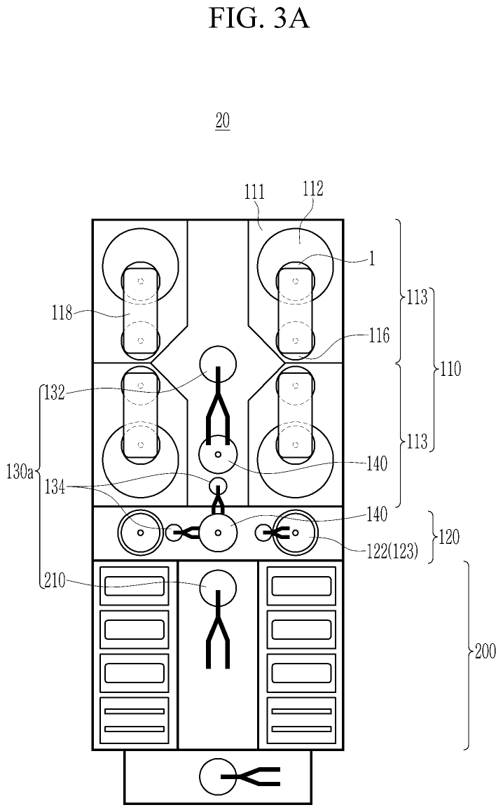

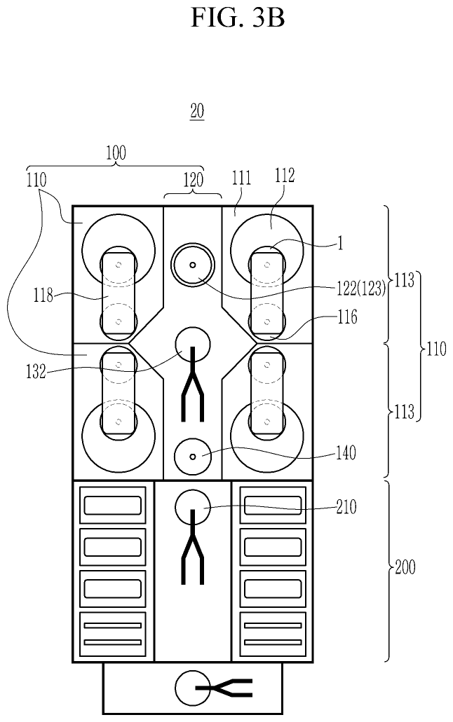

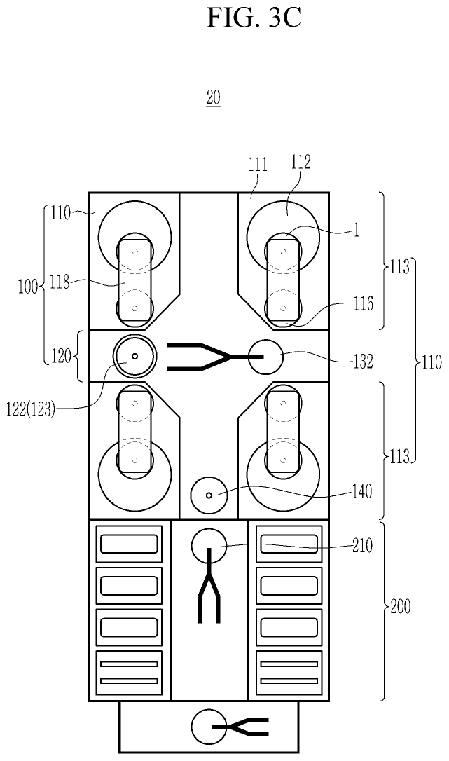

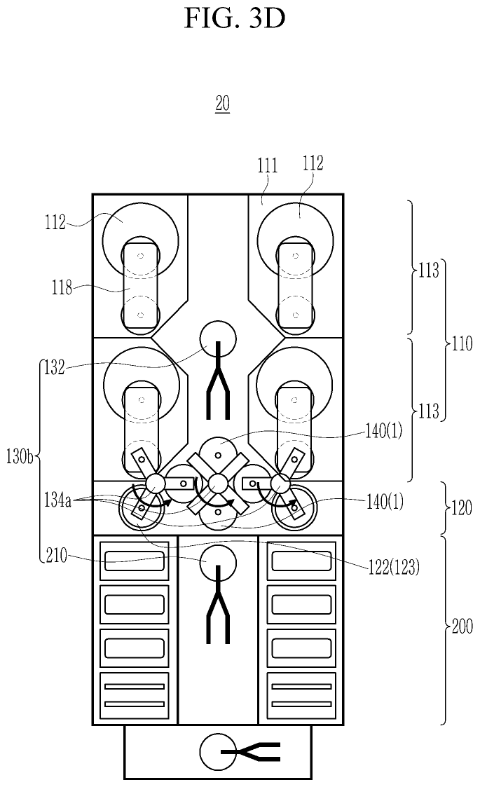

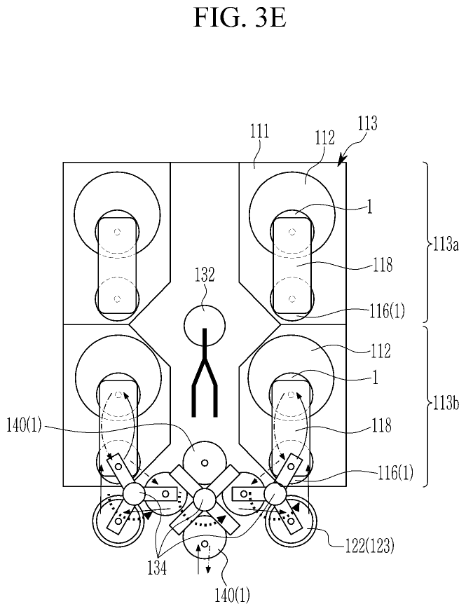

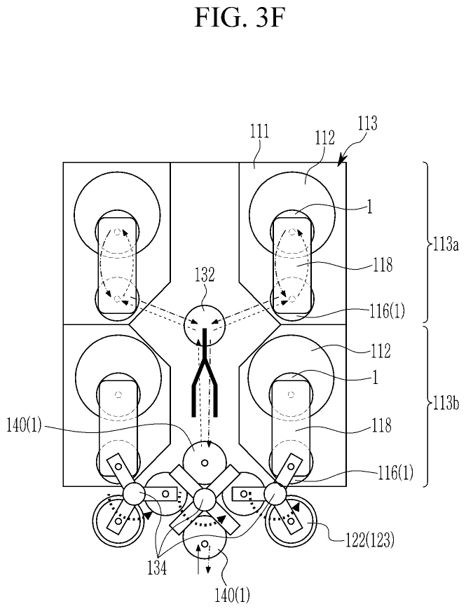

FIGS. 3A, 3B, and 3C are diagrams to describe a substrate processing system according to another embodiment.

FIGS. 3A to 3C illustrate the substrate processing system 20. The substrate processing system 20 may include the substrate polishing device 10 including the first polishing module 110 including the plurality of first polishing units 113 having the first polishing pads 112. The substrate processing system 20 may also include the second polishing module 120 including at least one second polishing unit 123 having the second polishing pad 122. The substrate processing system 20 may further include a cleaning module 200 disposed close to the substrate polishing device 10 to perform a cleaning process, and the transfer module 130 transferring the substrate 10 from the substrate polishing device 10 and the cleaning module 200. The diameter of the second polishing pad 122 is smaller than the diameter of the first polishing pad 112, and the second polishing module 120 may be disposed between the first polishing module 110 and the cleaning module 200 or may disposed within the first polishing module 110.

The second polishing module 120 may be disposed between the first polishing module 110 and the cleaning module 200 on one side close to the first polishing module 110, as shown in FIG. 3A.

According to the present disclosure, the substrate processing system 20 is a system that further includes the cleaning module 200 in comparison to the substrate polishing device 10. Hereinafter, the descriptions to the same components and features as in the above embodiment of the inventive concepts will be omitted for the purpose of ease of explanation and brevity. Differences between the present embodiment of the inventive concepts and the above embodiment will be mainly described. As illustrated in FIG. 3A, the substrate processing system 20 may include a transfer module 130a transferring the substrate 1 among the first polishing module 110, the second polishing module 120, and the cleaning module 200. The transfer module 130a may include the first transfer module 132 transferring the substrate 1 within the polishing module 110, the second transfer module 134 transferring the substrate 1 from the first polishing module 110 to the second polishing module 120, and a third transfer module 210 transferring the substrate 1 within the cleaning module 200.

Subsequent to the second polishing process performed by the second polishing module 120 as described above (e.g., with respect to FIG. 2A), the substrate 1 may be transferred to the cleaning module 200 for a cleaning process. The transfer of the substrate 1 to the cleaning module 200 may be performed by the third transfer module 210 moving within the cleaning module 200.

When the substrate 1 is transferred to each of the first polishing module 110, the second polishing module 120, and the cleaning module 200, the transfer module 130a may transfer the substrate 1 after placing the substrate 1 on the second holder 140, but the substrate 1 may be transferred without being on the second holder 140.

As illustrated in FIG. 3A, the first polishing module 110 may be disposed on a first side of the second polishing module 120 and the cleaning module 200 may be disposed on a second side of the second polishing module 120. For example, the second polishing module 120 may be disposed between the first polishing module 110 and the cleaning module 200.

In other embodiments, as shown in FIGS. 3B and 3C, the second polishing module 120 may be disposed in a passage between each chamber 111 of the first polishing module 110.

Referring to FIGS. 3B and 3C, where the first polishing module 110 includes at least four first polishing units 113, the second polishing module 120 may be disposed between a plurality of chambers 111 provided within the first polishing module 110.

FIG. 3B shows the second polishing module 120 disposed between chambers 111 along a direction from the first polishing module 110 to the cleaning module 200, and FIG. 3C shows the second polishing module 120 disposed between the chambers 111 along a direction perpendicular to the direction from first polishing module 110 to cleaning module 200.

In the embodiments as shown in FIGS. 3B and 3C, the transfer from the first polishing module 110 to the second polishing module 120 may be performed by the first transfer module 132, and the transfer from the second polishing module 120 to the cleaning module 200 may be performed by the third transfer module 210.

Although not shown, the first transfer module 132 and the second transfer module 134 may perform transfer from the first polishing module 110 to the second polishing module 120.

In the drawing, only the process sequentially progressing through the first polishing module 110, the second polishing module 120, and the cleaning module 200 has been described in the transfer direction of the substrate 1, but the transfer direction is not limited thereto.

After the second polishing process is performed first in the second polishing module 120, the first polishing process may be performed in the first polishing module 110, or the second polishing process in the second polishing module 120 may further proceed after the first polishing process is performed in the first polishing module 120. The processing process of the substrate 1 may be freely performed in any order depending on the needs of each substrate 1.

FIG. 3D is a diagram illustrating a substrate processing system according to another embodiment.

FIG. 3D shows the same structure of the substrate processing system 20 as that of FIG. 3A, but has a different transfer module 130b that includes first transfer module 132, third transfer module 210, and a second transfer module 134a, wherein the second transfer module 134a may be a turret type with a plurality of arms rotating about an axis vertical to the substrate 1 as shown in FIG. 3D.

The second transfer module 134a may be a turret type, in which case a plurality of arms may rotate to transfer the substrate 1 as the substrate 1 is transferred from the first polishing module 110 to the second polishing module 120.

The first transfer module 132 and the third transfer module 210 may be in the form of a robot and may be respectively disposed in the first polishing module 110 and the cleaning module 200. The second transfer module 134a in a turret type may be disposed near the boundary between the first and second regions (e.g., the first polishing module 110 and the second polishing module 120).

In the first polishing unit 113 shown at the top, the first transfer module 132 may transfer the substrate 1 to the second holder 140 disposed in the first region, as shown in FIG. 3A. The first polishing unit 113 shown at the bottom may transfer the substrate 1 directly to the second polishing module 120 via the turret-type second transfer module 134a disposed at the boundary of the first and second regions, without relying on the first transfer module 132.

The process of transferring the substrate 1 from each first polishing unit 113 to the second polishing module 120 in FIG. 3D will be described in detail through FIGS. 3E and 3F.

FIGS. 3E and 3F are diagrams to describe the operation process of the substrate processing system according to FIG. 3D.

The first polishing unit 113 may be divided into an upper first polishing unit 113ashown at the top, and a lower first polishing unit 113b shown at the bottom, depending on the transport means. FIG. 3E is a diagram for describing the transfer of the substrate 1 from the lower first polishing unit 113b to the second polishing module 120.

The lower first polishing unit 113b, shown below, which is disposed in close proximity to the second region where the second polishing module 120 is disposed, may enter the second region directly through the turret-type second transfer module 134a (second transfer modules disposed at both ends) disposed at the boundary of the first and second regions, rather than by the robot-type first transfer module 132, and may also be loaded directly onto the second polishing pad 122.

As shown, the plurality of rotating arms of the second transfer module 134a may have a length that allow them to access both the first holder 116 in the chamber 111 of the first polishing unit 113 and the second polishing pad 122 of the second polishing module 120, such that the substrate 1 gripped (such as bonded or loaded) to the arm may be transferred from the first holder 116 to the second polishing pad 122 as the plurality of arms rotate about an axis vertical to the surface of the substrate 1.

As described above, the substrates 1 transferred directly from the first holder 116 in the lower first polishing unit 113b to the second polishing pad 122 may be transferred to the second holder 140 disposed within the second region by rotation of the second transfer module 134a in the center, after the second polishing process has been performed.

In the next process, although not shown, the substrate 1 placed on the second holder 140 in the second region may be transferred to the cleaning module 200 through the third transfer module 210 for a cleaning process.

FIG. 3F is a diagram for describing the transfer of the substrate 1 from the upper first polishing unit 113a shown at the top to the second polishing module 120.

As shown in FIG. 3A, the first transfer module 132 in the form of a robot serves to transfer the substrate 1 from the first polishing module 110 to the second holder 140 disposed in the first region close to the second polishing module 120.

The substrate 1 transferred to the second holder 140 disposed in the first region may be transferred to the second holder 140 disposed in the second region through rotation of the turret-type second transfer module 134 disposed in the center, and may be transferred and loaded from the second holder 140 to the second polishing pad 122 through the second transfer modules 134 disposed at both ends.

Although not illustrated, the transfer module 130 may be equipped with a distance detection sensor, when both the robot-type first transfer module 132 and the turret-type second transfer module 134a are disposed.

Depending on embodiments, a distance detection sensor may be disposed to prevent collision between the first transfer module 132 and the second transfer module 134a, and a distance detection sensor may be disposed in at least one of the first transfer module 132 and the second transfer module 134a.

In addition, when a plurality of turret-type second transfer modules 134a are disposed, the plurality of arms may collide with each other according to each rotation. As a result, there is a possibility that the substrate 1 being transferred may be damaged. To prevent this, a distance detection sensor for preventing collision between the second transfer modules 134a may be further disposed.

In another embodiment, the rotation speeds of the turret-type second transfer modules 134a may be synchronized to prevent mutual collision.

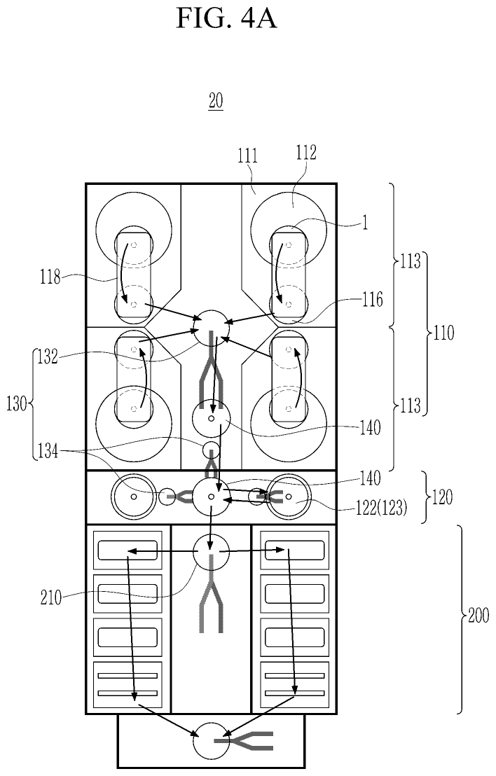

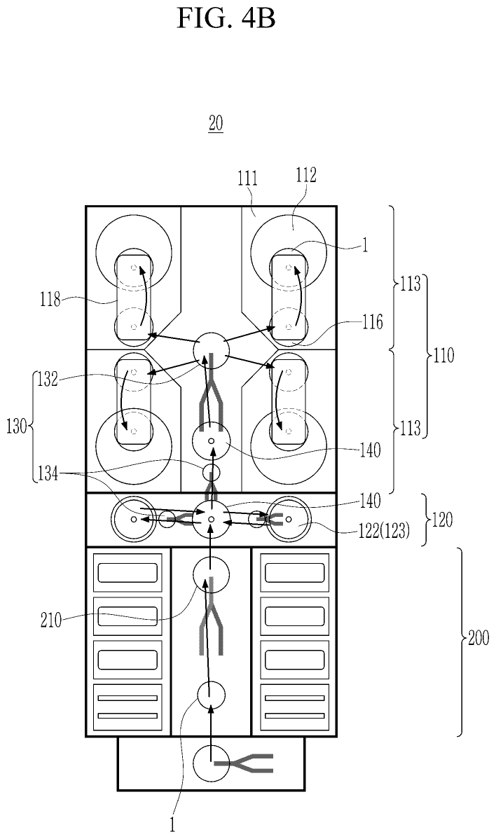

FIGS. 4A and 4B are diagrams to describe the operation process of the substrate processing system according to FIG. 3A.

FIGS. 4A and 4B show an embodiment of a structure in which the second polishing module 120 is disposed between the first polishing module 110 and the cleaning module 200, and the robot-type first transfer module 132, the second transfer module 134 and the third transfer module 210 are shown transferring the substrate 1.

First, FIG. 4A illustrates the process in which the substrate 1 loaded on the first polishing pad 112 of the first polishing unit 113 passes through the second polishing module 120 and the cleaning module 200.

First, the substrate 1 loaded on the first polishing pad 112 may be transferred to the first holder 116 in the chamber 111 by the substrate transfer portion 118, and the substrate 1 in the first holder 116 may be placed on the second holder 140 disposed in the first region so that the substrate 1 approaches the second region, as the transfer module 132 disposed in the first region moves.

The substrate 1 placed on the second holder 140 disposed in the first region is transferred to the second holder 140 disposed in the second region by the second transfer module 134 moving within the first region. The substrate 1 may subsequently be loaded from the second holder 140 onto the second polishing pad 122 by the second transfer module 134 moving within the second region.

In order to transfer the substrate 1 to the cleaning process after the second polishing process is completed, the substrate 1 may be transferred from the second polishing pad 122 to the second holder 140 disposed in the second region by the second transfer module 134. Subsequently, the third transfer module 210 may transfer the substrate 1 placed on the second holder 140 disposed in the second region to the cleaning module 200 for the cleaning process, and then the polishing and cleaning processes may be completed.

FIG. 4A shows that substrate processing is ended after the substrate 1 sequentially goes through the first polishing process, the second polishing process, and the cleaning process once each.

FIG. 4B shows the process of entering the substrate 1, in which the second polishing process is first performed twice, and then the first polishing process is performed.

First, the substrate I may enter the region where the second polishing module 120 is disposed by the third transfer module 210 from one side where the cleaning module 200 is disposed. Specifically, the third transfer module 210 may place the substrate 1 on the second holder 140 disposed in the second region.

The substrate I placed on the second holder 140 disposed in the second region is loaded onto the second polishing pad 122 by the second transfer module 134, and thus the second polishing process may be performed. Referring to FIG. 4B, it can be seen that the substrate 1 is transferred once from the second holder 140 disposed in the second region to the second polishing module 120 disposed on the left and then back again, resulting in two polishing processes.

After two second polishing processes are ended, the second transfer module 134 disposed in the first region may transfer and place the substrate 1 on the second holder 140 disposed in the first region. The substrate I placed on the second holder 140 disposed in the first region may be transferred to each first polishing unit 113 through the first transfer module 132.

When the first transfer module 132 transfers the substrate 1 from the second holder 140 disposed within the first region to the first holder 116 in each chamber 111, the substrate transfer portion 118 disposed in each chamber 111 may load the substrate 1 from the first holder 116 to the first polishing pad 112 of the first polishing unit 113 to perform the first polishing process.

The substrate polishing method according to the present disclosure uses the substrate polishing device 10 and the substrate processing system 20, and may include performing the first polishing process in the first polishing module 110 including the first polishing unit 113 (S100), performing the second polishing process during at least one of before and after (i.e., before and/or after) the first polishing process in the second polishing module 120 including the second polishing unit 123 (S200), and transferring the substrate 1 from the first polishing module 110 to the second polishing module 120 or from the second polishing module 120 to the first polishing module 110 (S300).

The order of the first polishing process and the second polishing process is free (i.e., may be varied), and the process may be repeated depending on the necessary processes.

The second polishing process in the present disclosure is performed before and after the first polishing process in accordance with the necessary process, parts, and conditions for each substrate 1. The diameter of the second polishing pad 122 of the second polishing unit 123 may be smaller than the diameter of the first polishing pad 112 of the first polishing unit 113.

Accordingly, the second polishing unit 123 has a smaller equipment size compared to the first polishing unit 113, and there are always fewer of the second polishing units 123 disposed so that the number of the second polishing units 123 disposed on the second polishing module 120 is less than 1 relative to the number of the first polishing units 113 disposed on the first polishing module 110, and the area of the second region where the second polishing module 120 is disposed may be smaller than the area of the first region where the first polishing module 110 is disposed.

In addition, the first region where the first polishing module 110 is disposed is disposed adjacent to the second region where the second polishing module 120 is disposed, or the second region is disposed within the first region. Therefore, it is not necessary to separately add a moving line of the substrate 1 between each first polishing module 110 and the second polishing module 120, which may increase efficiency and productivity in substrate processing.

The substrate transfer step S300 is a transfer from the first polishing module 110 to the second polishing module 120, wherein the substrate 1 unloaded from the first polishing pad 112 of the first polishing unit 113 and placed on the first holder 116 may be transferred by the first transfer module 132 from the first region to the second region close to the first holder 116, the second transfer module 134 may receive and place the substrate 1 on the second holder 140 disposed in the second region, and then load the substrate 1 onto the second polishing pad 122.

Alternatively, in the transfer from the second polishing module 120 to the first polishing module 110, the second transfer module 134 may unload the substrate 1 from the second polishing pad 122 and transfer the substrate 1 to the second holder 140, the second transfer module 134 moving within the first region may transfer the substrate 1 placed on the second holder 140 to the first transfer module 132, and then the first transfer module 132 may transfer the substrate 1 to the first holder 116. The second holder 140 for placing the substrate 1 may be additionally disposed in a position close to the second region where the second polishing module 120 is disposed among the first regions where the first polishing module 110 is disposed. In addition, when transferring the substrate 1 between the first transfer module 132 and the second transfer module 134 in the transferring of the substrate (S300), the substrate 1 may be placed on the second holder 140.

The second polishing process may be a process in which at least one of polishing time, polishing amount, and distribution importance is lower than that of the first polishing process. For example, the second polishing process may be a process of removing the roughness of the substrate 1 by buffing before the first polishing process, or may be a process feeding a protective agent to the substrate 1 before the first polishing process.

Alternatively, the second polishing process may be at least one of the edge polishing and bevel etching, and particles such as ceria particles may also be removed through buffing CMP by performing the second polishing process before and after the first polishing process. FIGS. 5A to 5E are diagrams to describe a process of substrate loading to the second polishing module according to an embodiment.

Referring to FIGS. 5A to 5E, each of the second polishing units 123 included in the second polishing module 120 may include a second supporting member 124 that is elevatable and rotatable about the axis in a direction vertical to the substrate 1, and the second polishing pad 122 disposed on the upper surface of the second supporting member 124 to load (e.g., support) the substrate 1 and polish the substrate 1 during the polishing process. The diameters of the second supporting member 124 and the second polishing pad 122 are shown to be slightly larger than the diameter of the substrate 1, but may be smaller than the diameter of the substrate 1 depending on embodiments.

In addition, a second head portion 126 positioned on the upper portion of the second polishing pad 122 may support the substrate 1 through the lower surface. The second head portion 126 is elevatable and rotatable about the axis in the direction vertical to the second supporting member 124, and may press the substrate 1 from the top of the second polishing pad 122 toward the second polishing pad 122.

FIGS. 5A to 5E show a process of loading the substrate 1 from the second holder 140 to the second polishing pad 122 through the second transfer module 134. In addition to the configuration of the second polishing unit 123 in FIG. 2C, the robot-type second transfer module 134 is further shown, together with the second holder 140 disposed near the second polishing unit 123 to place the substrate 1 before loading the substrate 1 onto the second polishing pad 122.

First, FIG. 5A shows a second transfer module 134 transferring the substrate 1 placed on the second holder 140 to a position between the second polishing pad 122 and the second head portion 126 of the second polishing unit 123. At this time, the second supporting member 124 may move up and down or rotate about the axis, and the second head portion 126 may rise about the axis, so that the substrate 1 may be disposed and adjusted to fit the area to be polished.

FIGS. 5B, 5C show the second head portion 126 descending so that the lower surface of the second head portion 126 and the top surface of the substrate 1 are in contact, such that the second head portion 126 may vacuum chuck the substrate 1 (e.g., support the substrate 1 through the lower surface of the second head portion 126). After chucking, the second transfer module 134 may descend to be spaced from the substrate 1 and the second polishing pad 122.

FIG. 5D shows the second transfer module 134 leaving the second polishing unit 123 and rotating back to the second holder 140 after transferring the substrate 1 to the second polishing unit 123. FIG. 5E shows the second head portion 126 descending to allow the substrate 1 to contact with the second polishing pad 122.

Afterwards, the second polishing process may proceed. In the above process, a slurry is supplied between the surface of the substrate 1 and the polishing surface of the second polishing pad 122, sprinkled onto the second polishing pad 122, the surface to be ground of the substrate 1 is placed on the second polishing pad 122, and the surface of the substrate 1 is polished by relative rotation while the substrate 1 and the second polishing pad 122 are in contact while applying pressure through the second head portion 126.

The substrate polishing device 10, the substrate processing system 20, and the polishing method using the same according to the present disclosure may enable the substrates 1 to easily go through the second polishing process before or after the first polishing process by disposing the second polishing module 120 near or within the first region where the first polishing process is performed.

In addition, unlike in the first polishing process, in the second polishing process, the polishing work is performed according to the required area and conditions rather than polishing the entire substrate 1, so the equipment in the second polishing process may have a smaller size than the equipment used in the first polishing process, and the area occupied is also small, so that the second polishing process may be performed without significantly increasing the space of the entire polishing device.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A substrate polishing device, comprising:
a first polishing module disposed in a first region and including a plurality of first polishing units having first polishing pads;
a second polishing module disposed in a second region and including at least one second polishing unit having a second polishing pad; and
a transfer module configured to transfer a substrate between the first polishing module and the second polishing module,
wherein the second region is disposed adjacent to or within the first region, and a diameter of the second polishing pad is smaller than a diameter of the first polishing pad.

2. The substrate polishing device of claim 1, wherein:
the area of the second region is less than or equal to 70% the area of the first region.

3. The substrate polishing device of claim 1, wherein:
the number of the first polishing units is greater than the number of the second polishing units.

4. The substrate polishing device of claim 1, wherein:
the transfer module is a robot equipped with an articulated arm.

5. The substrate polishing device of claim 1, wherein:
the transfer module is a turret in which a plurality of arms rotate around an axis vertical to the substrate.

6. The substrate polishing device of claim 5, wherein:
the transfer module is equipped with a distance detection sensor.

7. The substrate polishing device of claim 1, wherein:
the transfer module comprises
a first transfer module configured to transfer the substrate within the first region; and
a second transfer module configured to transfer the substrate between the first region and the second region and within the second region.

8. The substrate polishing device of claim 1, wherein:
each of the plurality of first polishing units comprises
a chamber in which a first polishing process is performed;
a first supporting member configured to rotate within the chamber around a first axis extending in a first direction vertical to the substrate;
the first polishing pad disposed on the upper surface of the first supporting member to polish the substrate; and
a first head portion including a substrate supporter that is disposed on the lower surface of the first head portion and supports the substrate, the first head portion configured to
rotate around a second axis extending in the first direction, move in the first direction, and press the substrate from toward the first polishing pad.

9. The substrate polishing device of claim 1, wherein:
a diameter of at least one of the second polishing pad and an upper surface of a second supporting member disposed below the second polishing pad is less than or equal to 1.2 times the diameter of the substrate.

10. The substrate polishing device of claim 8, wherein:
a first holder disposed adjacent to the first polishing pad within the chamber and configured to hold the substrate before loading the substrate on the first polishing pad or after unloading the substrate from the first polishing pad; and
a substrate transfer portion configured to transfer the substrate between the first holder and the first polishing pad.

11. The substrate polishing device of claim 8, wherein:
a second holder for placing the substrate is disposed in the second region.

12. A substrate processing system, comprising:
a substrate polishing device including a first polishing module including a plurality of first polishing units having first polishing pads, and a second polishing module including at least one second polishing unit having a second polishing pad, wherein a diameter of the second polishing pad is smaller than a diameter of the first polishing pad;
a cleaning module disposed adjacent to the substrate polishing device to perform a cleaning process; and
a transfer module configured to transfer a substrate from the substrate polishing device and the cleaning module,
wherein the second polishing module is disposed between the first polishing module and the cleaning module or is disposed within the first polishing module.

13. The substrate processing system of claim 12, wherein:
the first polishing module includes at least four first polishing units,
the second polishing module is disposed between a plurality of chambers provided in the first polishing module.

14. The substrate processing system of claim 12, wherein:
the transfer module comprises
a first transfer module configured to transfer the substrate within the first polishing module;
a second transfer module configured to transfer the substrate from the first polishing module to the second polishing module; and
a third transfer module configured to transfer the substrate within the cleaning module.

15. A substrate polishing method, comprising:
performing a first polishing process in a first polishing module including a first polishing unit;
performing a second polishing process during at least one of before and after the first polishing process in a second polishing module including a second polishing unit; and
transferring the substrate from the first polishing module to the second polishing module or from the second polishing module to the first polishing module,
wherein a first region where the first polishing module is disposed is disposed adjacent to a second region where the second polishing module is disposed, or the second region is disposed within the first region, and
wherein a diameter of a second polishing pad of the second polishing unit is smaller than a diameter of a first polishing pad of the first polishing unit.

16. The substrate polishing method of claim 15, wherein:
in the transferring of the substrate,
a first transfer module transfers the substrate unloaded from the first polishing pad and placed in a first holder from the first region close to the second region, and a second transfer module receives the substrate and places the substrate in a second holder disposed in the second region, and then loads the substrate onto the second polishing pad, or
the second transfer module unloads the substrate from the second polishing pad and transfers the substrate to the second holder, the second transfer module moving in the first region transfers the substrate placed on the second holder to the first transfer module, and then the first transfer module transfers the substrate to the first holder.

17. The substrate polishing method of claim 15, wherein:
the second polishing process is a process in which at least one of polishing time, polishing amount, and distribution importance is low compared to the first polishing process.

18. The substrate polishing method of claim 15,
the second polishing process is a process in which roughness of the substrate is removed by buffing before the first polishing process.

19. The substrate polishing method of claim 15, wherein:
the second polishing process is a process in which a protective agent is fed to the substrate before the first polishing process.

20. The substrate polishing method of claim 15, wherein:
the second polishing process is at least one of edge polishing and bevel etching.
